(19) United States
(12) Patent Application Publication
(10) Pub. No.: US 2023/0032893 A1
(43) Pub. Date: Feb. 2, 2023

(54) POWER MODULE

(71) Applicant: Danfoss Silicon Power GmbH, Flensburg (DE)

(72) Inventor: Jörg BERGMANN, Nordborg (DK)

(21) Appl. No.: 17/781,407

(22) PCT Filed: Nov. 13, 2020
(86) PCT No.: PCT/EP2020/082050

§ 371 Date: Jun. 1, 2022

(30) Foreign Application Priority Data
Dec. 3, 2019 (DE) 10 2019 132 899.3

(51) Int. Cl. H01L 25/07; H01L 25/18

(52) U.S. Cl. CPC H01L 25/072; H01L 25/18; H01L 2224/48137; H01L 24/48

(57) ABSTRACT

A power module (2) including a plurality of rectangular electrical power components (4, 4′) arranged on a substrate (6). The sides of at least a subset of the rectangular electrical power components (4, 4′) are not orthogonal to a line (12, 12′) that passes through the geometric centre (C) of the rectangular electrical power components (4, 4′) of the subset and extends orthogonal to a side (L, M) of the substrate (6).

### CROSS-REFERENCE TO RELATED APPLICATION

This application is a National Stage application of International Patent Application No. PCT/EP2020/082050, filed on Nov. 13, 2020, which claims priority to German Application No. 10 2019 132 899.3, filed Dec. 3, 2019, each of which is hereby incorporated by reference in its entirety.

### TECHNICAL FIELD

The present invention relates to a power module comprising a plurality of rectangular electrical power components arranged on a substrate.

### BACKGROUND

Developers are constantly trying to increase the power density of power modules for electric drives, electric steering, electric converters and electric chargers in order to be competitive. On the other hand, in many applications the outer dimensions of the power module are crucial. Accordingly, it would be desirable to be able to increase the power density without increasing the outer dimensions of the power module, or alternatively to lower the outer dimensions of the power module while maintaining the power density.

It is an object of the invention to provide a power module, wherein the power density can be increased without increasing the outer dimensions of the power module.

It is also an object to provide a power module, in which it is possible to use wire bonding to electrically connect the electrical power components to other electrical power components or the packaging of the power module.

### SUMMARY

The objects of the present invention can be achieved by a power module as defined in claim 1. Preferred embodiments are defined in the dependent subclaims, explained in the following description and illustrated in the accompanying drawings.

The power module according to the invention is a power module comprising a plurality of rectangular electrical power components arranged on a substrate, wherein the sides of at least a subset of the rectangular electrical power components are not orthogonal to a line that:
A) passes through the geometric centre of the rectangular electrical power components of the subset and
B) extends orthogonal to a sides of the substrate.

Hereby, it is possible to increase the power density of the power module without increasing the outer dimensions of the power module. Moreover, it is possible to use wire bonding to electrically connect the electrical power components to other electrical power components or its packaging.

In one embodiment, the substrate is rectangular and thus has two parallel second sides.

In one embodiment, for all the sides of all the rectangular electrical power components none of the sides of all the rectangular electrical power components are orthogonal to the line passing through the geometric centre of the rectangular electrical power component and extending orthogonal to a side of the substrate.

In one embodiment, none of the sides of a subset of the rectangular electrical power components are parallel to any of the sides of the substrate.

In one embodiment, none of the sides of any of the rectangular electrical power components are parallel to any of the sides of the substrate.

In one embodiment, at least some of the rectangular electrical power components are square. This may be an advantage since many power semiconductors are square.

In one embodiment, all the rectangular electrical power components are square.

In one embodiment, the angle between one or more of the rectangular electrical power components and a first side of the substrate is within the range 15-75°.

In one embodiment, the angle between one or more of the rectangular electrical power components and the first side of the substrate is within the range 30-60°.

In one embodiment, the angle between one or more of the rectangular electrical power components and the first side of the substrate is within the range 40-50°.

In one embodiment, the angle between one or more of the rectangular electrical power components and the first side of the substrate is 45°.

In one embodiment, at least some of the electrical power components are arranged in groups of two or more electrical power components arranged side by side and being spaced less than 2 mm.

In one embodiment, the electrical power components being arranged side by side are spaced 0.1-1 mm.

In one embodiment, the electrical power components being arranged side by side are spaced 0.6-0.8 mm.

In one embodiment, the electrical power components being arranged side by side are spaced 0.65-0.75 mm.

In one embodiment, the geometry of some of the electrical power components is 5×5 mm. In one embodiment, the geometry of some of the electrical power components is 3.5×7.5 mm.

In one embodiment, at least some of the groups are arranged in rectangular group areas comprising two or more electrical power components.

In one embodiment, the rectangular group areas are arranged along parallel lines.

In one embodiment, some of the electrical power components within the groups are offset along a direction perpendicular to the lines.

In one embodiment, all electrical power components within the groups are offset along a direction perpendicular to the lines.

In one embodiment, the adjacent electrical power components of the groups are offset:

in a first direction extending parallel to the lines and

in a second direction extending perpendicular to the lines.

In one embodiment, the rectangular electrical power components are symmetrically arranged on the substrate.

In one embodiment, the rectangular electrical power components are power semiconductors. Examples of such semiconductors might be IGBTs, diodes, MOSFETs, and the semiconductor technology in use might be silicon or silicon carbide, as examples.

In one embodiment, all electrical power components have a side extending parallel to a side of each of the remaining electrical power components. This means that all electrical power components extend parallel to each other. Accordingly, it is possible to position the electrical power components onto the substrate in a very compact and space saving manner.

In one embodiment, the substrate is a Direct Copper Bonding (DCB) substrate.

### BRIEF DESCRIPTION OF THE DRAWINGS

The invention will become more fully understood from the detailed description given herein below. The accompanying drawings are given by way of illustration only, and thus, they are not limitative of the present invention. In the accompanying drawings:

FIG. 1 shows a top view of a power module according to the invention;

FIG. 2 shows a top view of another power module according to the invention;

FIG. 3A shows a schematic top view of a prior art power module;

FIG. 3B shows a schematic view of a power module according to the invention;

FIG. 4A shows a schematic view of a power module according to the invention;

FIG. 4B shows a close-up view of a portion of the power module shown in FIG. 4A;

FIG. 5A shows a close-up view of a section of the substrate of a prior art power module;

FIG. 5B shows a close-up view of a section of the substrate of a power module according to the invention;

FIG. 6A shows a top view of a power module according to the invention;

FIG. 6B shows a cross-sectional view of a power module according to the invention and

FIG. 6C shows a cross-sectional view of a power module according to the invention, wherein the substrate is mounted on a baseplate.

### DETAILED DESCRIPTION

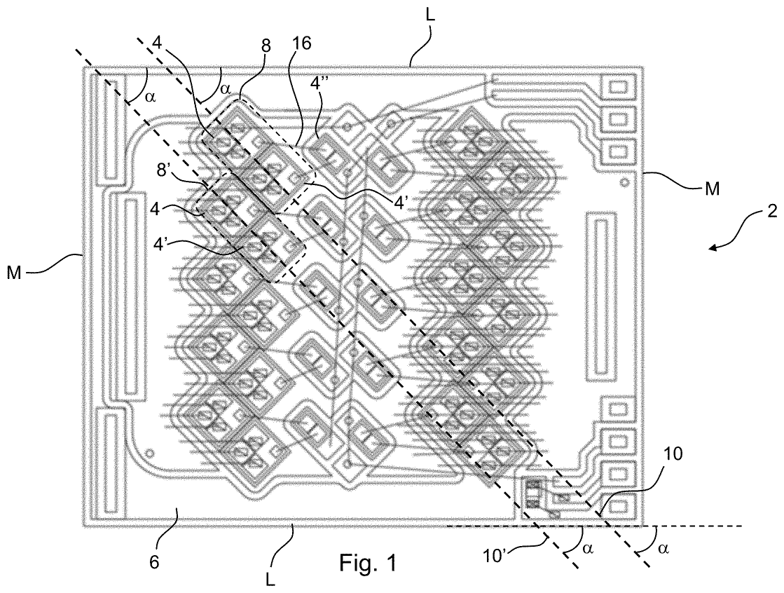

Referring now in detail to the drawings for the purpose of illustrating preferred embodiments of the present invention, a power module 2 of the present invention is illustrated in FIG. 1A.

FIG. 1 illustrates a top view of a power module 2 according to the invention. The power module 2 comprises a plurality of rectangular electrical power components 4, 4′, 4″ arranged on a substrate 6 having two parallel first sides L and two parallel second sides M extending perpendicular to the first sides L.

It can be seen that a first square electrical power component 4 and a second square electrical power component 4′ are arranged side by side to constitute a first group 8. An additional first square electrical power component 4 and an additional second square electrical power component 4′ are arranged side by side to constitute a second group 8′ arranged adjacent to the first group 8.

It can be seen that the first group 8 extends along a first line 10, whereas the second group 8 extends along a second line 10′ extending parallel to the first line L. The angle α between the lines 10, 10′ and the side L is indicated. It can be seen that the angle α is approximately 45°.

As all the electrical power components 4, 4′ of the groups 8, 8′ comprise a side extending parallel to the line 10, 10′, all electrical power components 4, 4′ of the groups 8, 8′ are angled about 45 degrees relative to the first sides L.

The second electrical power component 4′ of the first group 8 is electrically connected to a third electrical power component 4″ by means of a wire bond 16. It can be seen that wire bonding has been used to establish interconnections between various of the electrical power components 4, 4′, 4″. Several of the adjacent wire bonds 16 extend parallel to each other.

By rotating the electrical power components 4, 4′, 4″ relative to the sides L, it is possible to arrange the wire bonds 16 in an a more compact manner (than the prior art solutions). Accordingly, it is possible to place the wire bonds 16 in an allowable manner even when the density (number of electrical power components per unit area) of the electrical power components 4, 4′, 4″ is higher than in corresponding prior art solutions.

In one embodiment, the adjacent electrical power components 4, 4′ are spaced apart less than 2 mm in order to save space.

In one embodiment, the adjacent electrical power components 4, 4′ are spaced apart less than 1 mm in order to save space.

In one embodiment, the adjacent electrical power components 4, 4′ are spaced apart in the range 0.6-0.8. This range has been found to constitute a suitable and practical solution taking into consideration the production positioning tolerances.

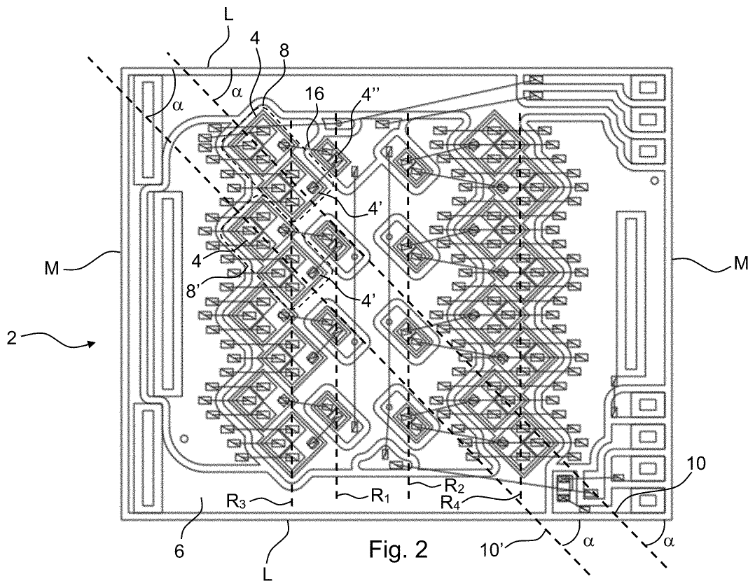

FIG. 2 illustrates a top view of another power module 2 according to the invention. The power module 2 comprises a plurality of groups 8, 8′ each comprising a first square electrical power component 4 arranged adjacent to a second square electrical power component 4′. The electrical power components 4, 4′ of each group 8, 8′ are offset from each other in a direction perpendicular to the line 10.

The power module 2 moreover comprises a plurality of rectangular electrical power components 4″. The electrical power components 4, 4′, 4″ are arranged on a substrate 6 having two parallel first sides L and two parallel second sides M extending perpendicular thereto.

The first group 8 extends along a first line 10, whereas the second group 8 extends along a second line 10′ extending parallel to the first line L. The angle α between the lines 10, 10′ and the side L is approximately 45°.

Wire bonds 16 are used to establish electrical connections between the electrical power components and other components of the power module.

It can be seen that the power module 2 comprises two centrally arranged rows R₁, R₂ of rectangular electrical power component 4″ arranged between two rows R₃, R₄ of groups 8, 8′. Each rectangular electrical power component 4″ is electrically connected to each of the electrical power components 4, 4′ of the adjacent group 8, 8′ by means of two wire bonds 16.

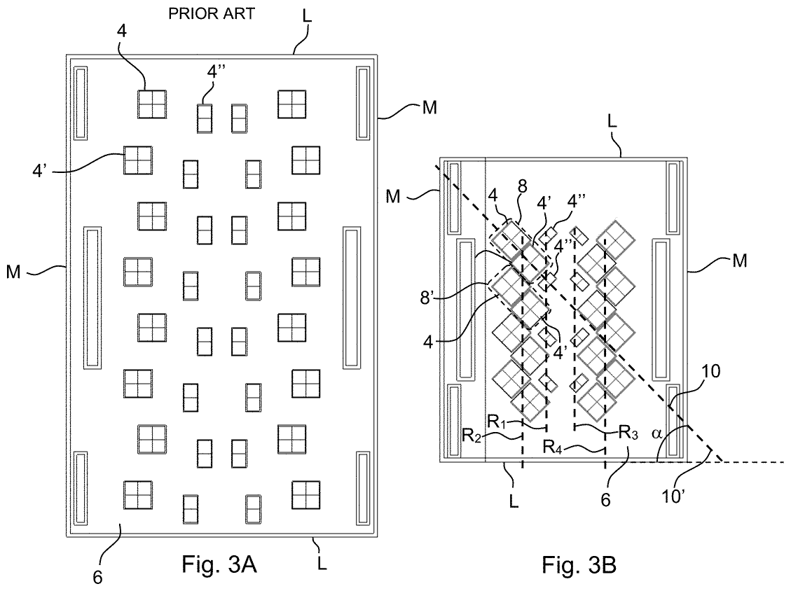

FIG. 3A illustrates a schematic top view of a prior art power module. A lot of space is required between adjacent electrical power components 4, 4′, 4″ to allow wire bonds (not shown) to extend between the electrical power components 4, 4′, 4″. This prior art solution, however, introduces the risk of using too long wire bonds which will increased the electrical resistance. The electrical power components 4, 4′, 4″ are arranged on a substrate 6 having two parallel first sides L and two parallel second sides M extending perpendicular thereto.

FIG. 3B illustrates a schematic view of a power module 2 according to the invention. The power module 2 is significantly smaller than the prior art power module shown in FIG. 3A, even though both power modules 2 comprise the same electrical power components 4, 4′, 4″. Accordingly, the power module 2 according to the invention is much more compact than the prior art power module.

The power module 2 moreover comprises a plurality of square electrical power components 4, 4′ and rectangular electrical power components 4″. The electrical power components 4, 4′, 4″ are arranged on a substrate 6 having two parallel first sides L and two parallel second sides M extending perpendicular thereto. The power modules 2 comprises four first groups 8, 8′ arranged along a row R₃ that extends parallel to the side M. The power modules 2 comprises four second groups arranged along a row R₄ extending parallel to the row R₃.

Each group 8 comprises two adjacent square electrical power components 4, 4′ extending along a line 10 being angled relative to the side L of the substrate 6. The angle α between the line 10 and the side L is approximately 45 degrees. The first electrical power components 4 of each group 8, 8′ is slightly offset in a direction perpendicular to the line 10 relative to the second electrical power components 4′ of the group 8, 8′.

Next to each of the groups 8, 8′ a rectangular electrical power component 4″ is arranged. The rectangular electrical power components 4″ are arranged along two rows R₁, R₂ extending parallel to the rows R₃, R₄.

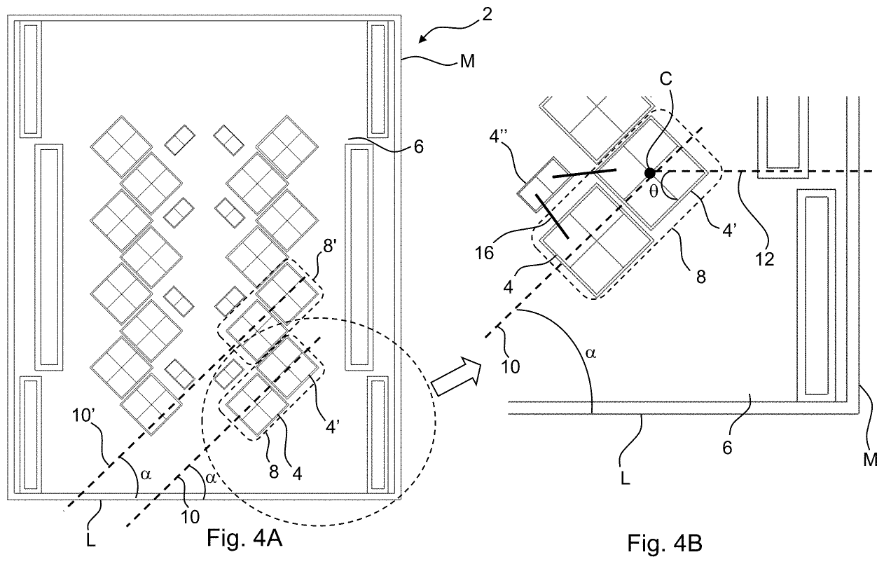

FIG. 4A illustrates a schematic view of a power module 2 according to the invention and FIG. 4B illustrates a close-up view of a portion of the power module 2 shown in FIG. 4A. The power module 2 comprises a plurality of square electrical power components 4, 4′ and rectangular electrical power components 4″ arranged on a substrate 6 having two parallel first sides L and two parallel second sides M extending perpendicular to the first sides L. The power modules 2 comprises four first groups 8, 8′ and four second groups arranged along two parallel rows extending parallel to the side M.

Each group 8, 8′ comprises two adjacent square electrical power components 4, 4′ extending along a line 10 being angled relative to the side L of the substrate 6. The angle α between the line 10 and the side L is approximately 45 degrees. The first electrical power components 4 of each group 8, 8′ is slightly offset in a direction perpendicular to the line 10 relative to the second electrical power components 4′ of the group 8, 8′.

Next to each of the groups 8, 8′ a rectangular electrical power component 4″ is arranged. The rectangular electrical power components 4″ are arranged along two rows extending parallel to the side M. Wire bonds 16 are used to electrically connect the rectangular electrical power component 4″ to the first and electrical power components 4, 4′ of the adjacent groups 8, 8′.

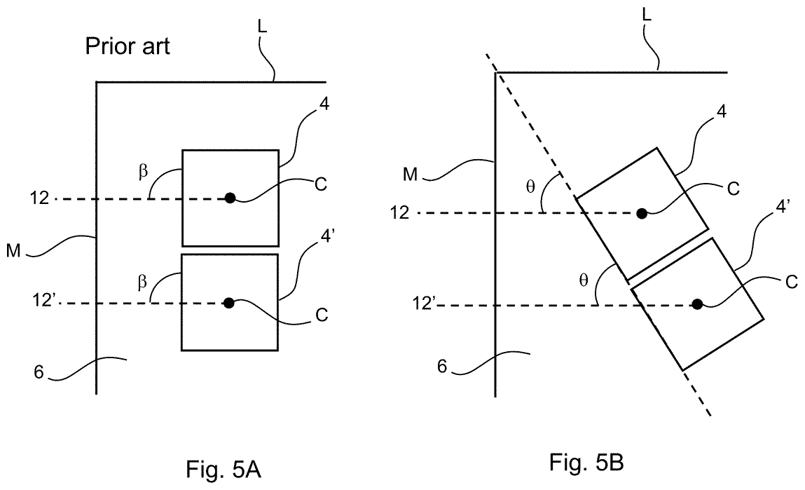

FIG. 5A illustrates a close-up view of a section of the substrate 6 of a prior art power module. A first electrical power component 4 and a second electrical power component 4′ are attached to the substrate 6. The substrate 6 has a first side L and a second side M extending parallel thereto. For each electrical power component 4, 4′, a dotted line 12, 12′ passing through the geometric centre C of the rectangular electrical power component 4, 4′ and extending orthogonal to the side M of the substrate 6 is indicated. It can be seen that the electrical power components 4, 4′ have a side extending orthogonal to the line 12, 12′. Accordingly, the indicated angle β is 90°. Therefore, each electrical power component 4, 4′ has a side that extends parallel to the side M of the substrate 6.

FIG. 5B illustrates a close-up view of a section of the substrate 6 of a power module according to the invention. The power module comprises a first electrical power component 4 and a second electrical power component 4′ being attached to the substrate 6. The substrate 6 has a first side L and a second side M. For each electrical power component 4, 4′, a dotted line 12, 12′ passing through the geometric centre C of the rectangular electrical power component 4, 4′ and extending orthogonal to the side M of the substrate 6 is indicated. The electrical power components 4, 4′ have a side that does not extend orthogonal to the line 12, 12′. The angle θ between the line 12, 12′ and the corresponding electrical power component 4, 4′ is indicated. It can be seen that the angle θ is approximately 45 degrees.

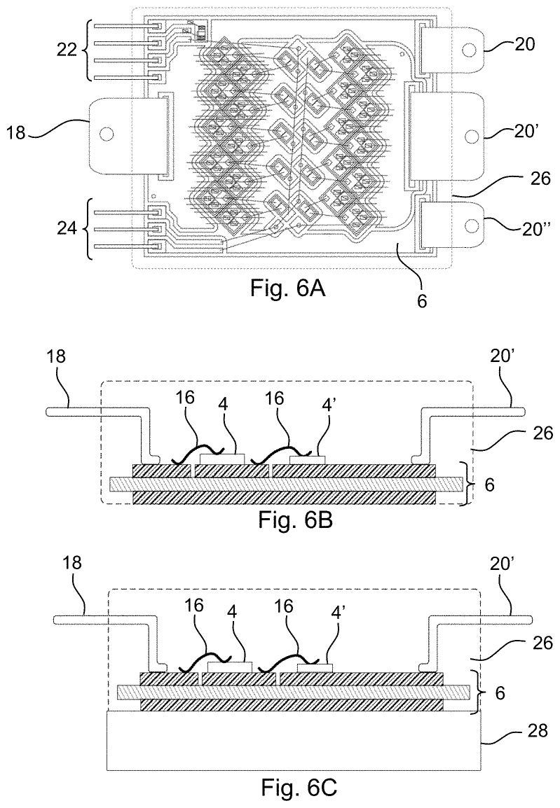

FIG. 6A illustrates a top view of a full power module according to the invention. The power module comprises a first group of control connections 22 and a second group of control connections 24 extending parallel to the longitudinal axis of the substrate 6 of the power module. A power connection (e.g. an AC power connection) is arranged between the two groups of control connections 22, 24. In the opposite side of the power module three power connections 20, 20′, 20″ are provided. The power connections 20, 20′, 20″ protrude from the substrate 6 in a direction parallel to the longitudinal axis of the substrate 6. The outer periphery of a moulding 26 is indicated with a dotted line.

FIG. 6B illustrates a cross-sectional view of a power module according to the invention and FIG. 6C illustrates a cross-sectional view of a power module corresponding to the one shown in FIG. 6B, wherein the substrate 6 is mounted on a baseplate 28 baseplate that functions as a heat spreader. It can be seen that the substrate 6 is a DCB substrate comprising a ceramic tile sandwiched between sheets of copper. Several electrical power components 4, 4′ are attached to the top layer of the DCB substrate 6. Moreover, wire bonds 16 are used to establish electrical interconnections. The outer periphery of a molding 26 is indicated with a dotted line in FIG. 6B and FIG. 6C, respectively.

While the present disclosure has been illustrated and described with respect to a particular embodiment thereof, it should be appreciated by those of ordinary skill in the art that various modifications to this disclosure may be made without departing from the spirit and scope of the present disclosure.

1. A power module comprising a plurality of rectangular electrical power components arranged on a substrate, wherein the sides of at least a subset of the rectangular electrical power components are not orthogonal to a line that:
passes through the geometric centre of the rectangular electrical power components of the subset and
extends orthogonal to a side of the substrate.

2. The power module according to claim 1, wherein for all the rectangular electrical power components none of the sides of all a rectangular electrical power component are orthogonal to the line passing through the geometric centre of the rectangular electrical power component and extending orthogonal to a side of the substrate.

3. The power module according to claim 1, wherein at least some of the rectangular electrical power components are square.

4. The power module according to claim 1, wherein all the rectangular electrical power components are square.

5. The power module according to claim 1, wherein an angle between one or more of the rectangular electrical power components and a first side of the substrate is within the range 30-60°.

6. The power module according to claim 1, wherein the angle between one or more of the rectangular electrical power components and the first side of the substrate is 45°.

7. The power module according to claim 1, wherein at least a subset of the electrical power components are arranged in groups of two or more electrical power components arranged side by side and being spaced apart less than 2 mm from each other.

8. The power module according to claim 7, wherein at least some of the groups are arranged in rectangular group areas comprising two or more electrical power components.

9. The power module according to claim 8, wherein the rectangular group areas are arranged along parallel lines.

10. The power module according to claim 9, wherein some of the electrical power components are offset along a direction perpendicular to the lines.

11. The power module according to claim 9, wherein the adjacent electrical power components of the groups are offset:
in a first direction extending parallel to the lines and
in a second direction extending perpendicular to the lines.

12. The power module according to claim 1, wherein all electrical power components have a side extending parallel to a side of each of the remaining electrical power components.
